(19) United States
(12) Patent Application Publication
(10) Pub. No.: US 2002/0046373 A1
(43) Pub. Date: Apr. 18, 2002

(54) MEMORY TESTING APPARATUS

(75) Inventors: SHAO-YU CHOU, HSINCHU (TW); YUE-DER CHIH, HSINCHU (TW)

Correspondence Address: NATH & ASSOCIATES, 1030 - 15TH STREET N.W., WASHINGTON, DC, 20005, US

(73) Assignee: Taiwan Semiconductor Manufacturing Co., Ltd., Hsinchu (TW)

(21) Appl. No.: 09/163,193

(22) Filed: Sep. 30, 1998

(51) Int. Cl. G11C 29/00

(52) U.S. Cl. 714/718; 714/720

(57) ABSTRACT

The present invention discloses a memory testing apparatus. The testing apparatus can be embedded on a chip with embedded memory block or a memory chip to reduce the testing time of memory blocks or memory devices. Through the selection of testing modes and the data processing of the processing device, the correctness of the output data of a memory block can be represent with the data state of a verifying data. The data output can be pre-processed and simplified as the verifying data to reduce the test time.

The apparatus for testing memories includes a memory block, a processing device, and a mode selecting device. An output data is read out from the memory block. The processing device is employed for processing the output data to generate a verifying data. The verifying data has a bit number less than a that of the output data. The mode selecting device is utilized for selecting testing modes of the processing device. In the case, the testing modes includes an all-high mode, an all-low mode, a data pattern verifying mode, and a by-pass mode.

### FIELD OF THE INVENTION

The present invention relates to an apparatus for testing memories, and more specifically, to a testing apparatus for testing memories devices and embedded memories with reduced time.

### BACKGROUND OF THE INVENTION

With the continuous progress in electric industry, more and more electrical device are developed and employed in daily life to improve convenience and living qualities. Computers, communications, and consumer products are identified to be most impressive applications of the twentieth century. In various applications, memory devices are inevitably utilized as vital elements in providing essential information and providing storage space for data exchange. In recent years, memory devices like flash memories, dynamic random access memories (DRAMs), and synchronous dynamic random access memories (SDRAM) are employed frequently in numerous applications.

In last four decades of developments, the semiconductor fabrication technology are researched and developed with an amazing rate to increase the packing density of devices on a single chip. The challenge on the yield of products is increased with the narrowing down of device feature sizes. In general, for ensuring the operation of the manufactured memory devices, a test process is performed. After the memory chips of the chips with embedded devices are finished, the operating characteristics are detected.

For improving the operational speed of the memory devices in data reading or writing, the bit number of the memory devices, namely the number of input or output pins, are increased with raised bandwidth of data output at each accessing. A memory device of the present stage may have a number of bits as high as 64 or above, in order to raise the speed of data exchange. However, in the testing of the memory devices with many pins, the accessible number of testing resource for each chip is limited. In the case of embedded memories on a functional chip with other operational blocks, the number of bits or pins which can be used for the embedded memory block is further limited.

For acquiring the complete output data pattern of the memory block or of the memory device under limited pin share, a serial scheme is usually used during the testing process. The serial scheme is utilized for sending data serially with reduced pins. In general, the parallel data output of multiple pins are directed to one pin or reduced number of pins to send the data in a serial way. Therefore, the number of pins used in the testing process can be reduced. However, the testing time is increased under increased accessing cycles, as the bandwidth of the memory being tested is raised. For example, the data output of a 64 bit memory at a timing edge may need 64 timing edges to send out the data with a single pin. Thus, the testing time can be tremendous if the bandwidth of the memory is too large for practical applications.

In light of above, an improved memory testing apparatus is highly needed to test memory devices or embedded memory blocks with reduced time to increase the efficiency of the testing process.

### SUMMARY OF THE INVENTION

A testing memory apparatus is disclosed in the present invention. The prior art problem of great time consumption on testing embedded memories or memory chip with a plurality of output bits can be solved. By the pre-processing of the processing device and the select of testing modes, the test time needed can be significantly reduced.

The testing apparatus in the present invention can includes a memory block and a processing device. An output data is read out from the memory block. The processing device processes the output data to generate a verifying data. The verifying data has a bit number less than that of the output data.

As a preferred embodiment, the memory block and the processing device are embedded on a single chip. The testing apparatus can further include a mode selecting device for selecting testing modes of the processing device. In the case, the testing modes include an all-high mode, an all-low mode, a data pattern verifying mode, and a by-pass mode.

### BRIEF DESCRIPTION OF THE DRAWINGS

The foregoing aspects and many of the attendant advantages of this invention will become more readily appreciated and better understood by referencing the following detailed description, when taken in conjunction with the accompanying drawings, wherein:

FIG. 1 illustrates a functional block diagram of the memory testing apparatus in accordance with the present invention; and

FIG. 2 illustrates an example of an input data pattern with a chessboard-like intervening distribution of high and low states.

### DETAILED DESCRIPTION OF THE PREFERRED EMBODIMENT

The present invention disclose a memory testing apparatus. The testing apparatus can be embedded on a chip with embedded memory block or a memory chip to reduce the testing time of memory blocks or memory devices. The prior art time-consuming problem of using the serial scheme can be minimized. Through the selection of testing modes and the data processing of the processing device, the correctness of the output data of a memory block can be represent with the data state of a verifying data. The data output can be pre-processed and simplified as the verifying data to reduce the test time. The memory chip or the functional chip with embedded memories can be tested with saved time and raised testing throughput.

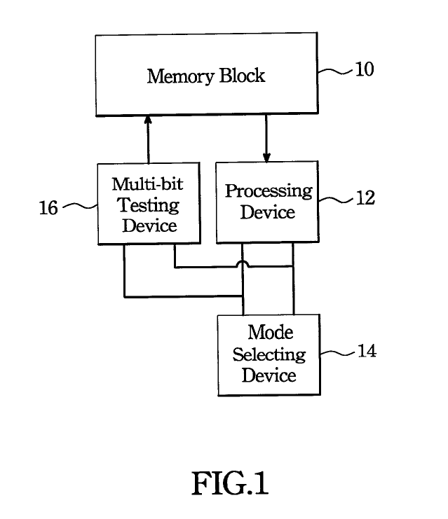

Referring to FIG. 1, a schematic functional block diagram of the testing apparatus of the present invention is illustrated. The testing apparatus for testing memories can include a memory block 10 and a processing device 12. The memory block 10 can be a memory array of a memory chip, or an embedded memory block of a functional chip like a general logic chip or an application specific integrated circuit (ASIC). The memory block 10 to be tested can be any kind of memory device like flash memories, dynamic random access memories (DRAM), and etc. In the case, a flash memory block is utilized only as an illustrative example of the present invention. In the testing process, an output data can be read out from the memory block 10. The output data can be read out in parallel at a time, with number of terminals corresponding to the bandwidth of the memory block, like 32 bits, 64 bits, or above. In the example of the flash memory block, an input data with the same number of bits is firstly wrote into the memory block 10. The output data is then read out to verify if data in all of the bits are correctly stored in the memory block 10.

The processing device 12 is then responsive to the memory block 10. The processing device 12 generates a verifying data from the output data. The verifying data is generated such that the verifying data has a bit number less than a bit number of the output data and the verifying data can represent essentially the correctness of the output data. In the case, a verifying data with only one bit to represent the correctness of the whole output data is employed. In the design of a chip with embedded logic function and memory devices, the memory block 10 and the processing device 12 can be embedded in a single chip. The correctness of the stored data in the memory block 10 can then be represent by the verifying data with reduced number of pins being used.

The testing apparatus can further include a mode selecting device 14. The mode selecting device 14 can be either a standing-along device or combined and embedded in the processing device 12. The mode selecting device 14 is employed for selecting testing modes of the processing device 12. As an example, four testing modes can be included in the embodiments. The four testing modes are an all-high mode, an all-low mode, a data pattern verifying mode, and a by-pass mode. For identifying the four different testing modes, two bits of information can be used preferably. In the preferred embodiments, the mode selecting device can be a data register with two or more bits for storing four or more states on representing the testing modes. If we represent a high state of logic as 1 and a low state of logic as 0, the data in the data register can be “0,1” for the all-high mode, “1,0” for the all-low mode, “1,1” for the data pattern verifying mode, and “0,0” for the by-pass mode.

Under the all-high mode, the memory block 10 is tested with an input data with all bits in a high state. Therefore, all bits of the output data should be at the high state if the memory block 10 is correctly functioned. The state of the verifying data can then be used to represent the success or the failure in data storage of the memory block 10. The verifying data is in a first state to represent that the memory block 10 is correctly functioned, if all bits of the output data are at the high state. In else conditions, namely when not all bits of the output data are at the high state or when a low state is presented in any bit of the output data, the verifying data is in a second state to represent that the memory block 10 is ill-functioned. As an example, the first state can be the high state and the second state can be the low state in the case.

Under the all-low mode, the memory block 10 is tested with an input data with all bits in a low state. Therefore, all bits of the output data should be at the low state if the memory block 10 is correctly functioned. The verifying data is in a first state to represent that the memory block 10 is correctly functioned, if all bits of the output data are at the low state. In else conditions, namely when not all bits of the output data are at the low state or when a high state is presented in any bit of the output data, the verifying data is in a second state to represent that the memory block 10 is ill-functioned. Same as above, the first state can be the high state and the second state can be the low state in the case.

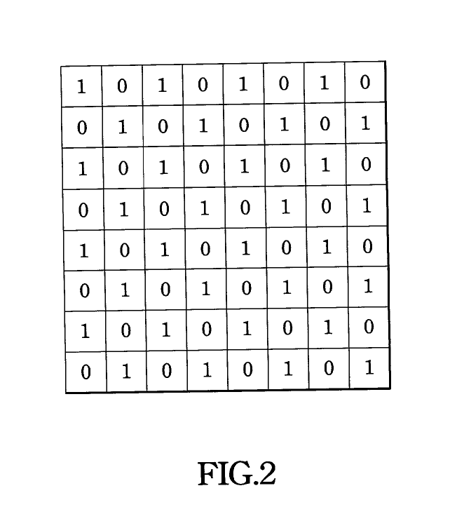

Under the data pattern verifying mode, the memory block 10 is tested with a prescribed input data. As an example, a chessboard like input data pattern with intervening high and low states, as shown in FIG. 2 for a 64 bits pattern, can be applied as the prescribed input data. Therefore, an output data pattern is expected to be the same, namely to toggle the input data pattern, if it is a correct pattern. The processing device 12 processes the output data by referencing the input data pattern. The verifying data is in a first state to represent that the memory block 10 is correctly functioned, if the data pattern of the output data is matched with the data pattern of an input data. However, if the data pattern of the output data is not matched with the data pattern of an input data bits, the verifying data is in a second state to represent that the memory block 10 is ill-functioned. In the same way, the first state can be the high state and the second state can be the low state in the case.

For providing the needed input data under different testing modes, a multi-bit testing device 16 can be included for providing an input data to the memory block and the processing device, as shown in FIG. 1. The multi-bit testing device 16 is responsive to the mode selecting device 14 to send out appropriate input data patterns, like a all-high's pattern, a all-low's pattern, or a high's and low's intervening pattern or chessboard pattern to be toggled by the processing device 12. In the data pattern verifying mode or a toggle mode, the corresponding pattern of the input data is send to the processing device 12.

Under the by-pass mode, a complicate or random input without a prescribed rule can be send to test the memory block 10. Under the by-pass mode, the verifying data can directly send out the data pattern of the output data with a serial scheme. In other words, the parallel output of plural bits are send out serially with one or more pins of the verifying data without being processed in the processing device 12. Under the by-pass mode, a well known serially output data buffer can be used and directly connected to the verifying data output terminal. The pattern can be send out in a serial way and then confirmed by the testing system.

For performing the above-identified operations, the processing device 12 can be a logic circuit or a combination of logic gates to check the output data by numerous logic and/or operations. The verifying data can then be generated to represent the operational characteristics. In general, since the all-high's mode, all-low's mode, and the toggle mode are of the most frequently applied testing modes, the testing apparatus provided in the present invention can save the test time significantly. The number of timing edges to check the function of a memory can be greatly reduced. With the embedded testing apparatus on the chip, the testing process is improved to be a time-saving and highly-efficient process.

As is understood by a person skilled in the art, the foregoing descriptions of the preferred embodiment of the present invention is an illustration of the present invention rather than a limitation thereon. It is intended to cover various modifications and similar arrangements included within the spirit and scope of the appended claims. The scope of the claims should be accorded to the broadest interpretation so as to encompass all such modifications and similar structures. While the preferred embodiment of the invention has been illustrated and described, it will be appreciated that various changes can be made therein without departing from the spirit and scope of the invention.

What is claimed is:

1. An apparatus for testing memories, said testing apparatus comprising:
a memory block, an output data being read out from said memory block; and
means for processing said output data to generate a verifying data, said verifying data having a bit number less than a bit number of said output data.

2. The testing apparatus of claim 1, wherein said memory block comprises a memory array selected from the group consisting of flash memories and dynamic random access memories.

3. The testing apparatus of claim 1, wherein said memory block and said processing means are embedded in a single chip.

4. The testing apparatus of claim 1, wherein said bit number of said verifying data is one.

5. The testing apparatus of claim 1 further comprising a mode selecting device for selecting testing modes of said processing means.

6. The testing apparatus of claim 5, wherein said testing modes comprising an all-high mode, an all-low mode, a data pattern verifying mode, and a by-pass mode.

7. The testing apparatus of claim 6, wherein under said all-high mode, said verifying data is in a first state if all bits of said output data are at a high state, and said verifying data is in a second state if not all said bits of said output data are at said high state.

8. The testing apparatus of claim 6, wherein under said all-low mode, said verifying data is in a first state if all bits of said output data are at a low state, and said verifying data is in a second state if not all said bits of said output data are at said low state.

9. The testing apparatus of claim 6, wherein under said data pattern verifying mode, said verifying data is in a first state if a data pattern of said output data is matched with a data pattern of said input data, and said verifying data is in a second state if said data pattern of said output data is not matched with said data pattern of said input data.

10. The testing apparatus of claim 6, wherein under said by-pass mode, said verifying data send out a data pattern of said output data with a serial scheme.

11. The testing apparatus of claim 1 further comprising a multi-bit testing device for providing an input data to said memory block and said processing means.

12. An apparatus for testing memories, said testing apparatus comprising:
a memory block, an output data being read out from said memory block;
a processing device for processing said output data to generate a verifying data, said verifying data having a bit number less than a bit number of said output data; and
a mode selecting device for selecting testing modes of said processing device, said testing modes comprising an all-high mode, an all-low mode, a data pattern verifying mode, and a by-pass mode.

13. The testing apparatus of claim 12, wherein said memory block comprises a memory array selected from the group consisting of flash memories and dynamic random access memories.

14. The testing apparatus of claim 12, wherein said memory block and said processing device are embedded in a single chip.

15. The testing apparatus of claim 12, wherein said mode selecting device comprises a data register.

16. The testing apparatus of claim 12, wherein under said all-high mode, said verifying data is in a first state if all bits of said output data are at a high state, and said verifying data is in a second state if not all said bits of said output data are at said high state.

17. The testing apparatus of claim 12, wherein under said all-low mode, said verifying data is in a first state if all bits of said output data are at a low state, and said verifying data is in a second state if not all said bits of said output data are at said low state.

18. The testing apparatus of claim 12, wherein under said data pattern verifying mode, said verifying data is in a first state if a data pattern of said output data is matched with a data pattern of said input data, and said verifying data is in a second state if said data pattern of said output data is not matched with said data pattern of said input data.

19. The testing apparatus of claim 12, wherein under said by-pass mode, said verifying data send out a data pattern of said output data with a serial scheme.

20. The testing apparatus of claim 12 further comprising a multi-bit testing device for providing an input data to said memory block and said processing device.
